(19) United States
(12) Patent Application Publication
(10) Pub. No.: US 2026/0181784 A1
(43) Pub. Date: Jun. 25, 2026

(54) FLEXIBLE CIRCUIT BOARD AND DISPLAY APPARATUS

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Xin Li, Beijing (CN); Yang Yue, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/834,308

(22) PCT Filed: Sep. 15, 2023
(86) PCT No.: PCT/CN2023/118985

§ 371 Date: Jul. 30, 2024

(51) Int. Cl. H05K 1/189; G02F 1/1333; G06F 1/16; H05K 1/02

(52) U.S. Cl. CPC H05K 1/189; G02F 1/133305; G06F 1/1652; H05K 1/028; H05K 2201/056

(57) ABSTRACT

The present disclosure discloses a flexible circuit board and a display apparatus. The flexible circuit board includes: a first board region, a second board region and a connection region arranged between the first board region and the second board region, a thickness of a part of the flexible circuit board corresponding to the first board region being greater than a thickness of a part of the flexible circuit board corresponding to the second board region, the part of the flexible circuit board corresponding to the second board region being used for bending, at least one first support layer and at least one metal layer being arranged at each of the first board region and the second board region, and the first support layer and the metal layer being laminated one on another in a thickness direction of the flexible circuit board; and a reinforcing structure arranged at the connection region.

### TECHNICAL FIELD

The present disclosure relates to the field of display technology, in particular to a flexible circuit board and a display apparatus.

### BACKGROUND

Along with the development of display technology, a flexible circuit board is provided with a hard board region and a soft board region, and the soft board region is bent to be coupled to an opposing part, so as to facilitate the space design of the whole machine. However, when bending the soft board region, stress concentration occurs in a connection region between the hard board region and the soft board region, resulting in fracture in the connection region. In this regard, the wiring of the flexible circuit board is adversely affected, a display defect occurs for a display apparatus, and a service life thereof is adversely affected.

### SUMMARY

An object of the present disclosure is to provide a flexible circuit board and a display apparatus, so as to improve the bending performance of the flexible circuit board, prevent the wiring of the flexible circuit board from being adversely affected, prolong the service life of the flexible circuit board, and ensure the display stability of the display apparatus.

In one aspect, the present disclosure provides in some embodiments a flexible circuit board, including: a first board region, a second board region and a connection region arranged between the first board region and the second board region, a thickness of a part of the flexible circuit board corresponding to the first board region being greater than a thickness of a part of the flexible circuit board corresponding to the second board region, the part of the flexible circuit board corresponding to the second board region being used for bending, at least one first support layer and at least one metal layer being arranged at each of the first board region and the second board region, and the first support layer and the metal layer being laminated one on another in a thickness direction of the flexible circuit board; and a reinforcing structure arranged at the connection region.

In a possible embodiment of the present disclosure, the flexible circuit board further includes second support layers arranged at the first board region, there is at least one second support layer extending to the second board region, and the second support layer at the second board region is configured to form at least a part of the reinforcing structure.

In a possible embodiment of the present disclosure, a dimension of the second support layer in the second board region is less than or equal to 1 mm in a direction from the first board region to the second board region.

In a possible embodiment of the present disclosure, there are at least two second support layers extending to the second board region; and in the second board region, the second support layer facing away from a bending direction of the second board region is a first extension layer, the second support layer facing the bending direction of the second board region is a second extension layer, and a dimension of the first extension layer is greater than a dimension of the second extension layer in the direction from the first board region to the second board region.

In a possible embodiment of the present disclosure, the quantity of metal layers in the first board region is greater than the quantity of metal layers in the second board region, and the metal layers in the second board region are arranged at a same layer as a part of the metal layers in the first board region; the quantity of first support layers in the first board region is greater than the quantity of first support layers in the second board region, and the first support layers in the second board region are arranged at a same layer as a part of the first support layers in the first board region; and a shielding layer is arranged at both sides of the flexible circuit board in the thickness direction.

In a possible embodiment of the present disclosure, at least one of the first support layers in the first board region extends to the second board region, and a part of the first support layers extending to the second board region are configured to form at least a part of the reinforcing structure; and/or at least one of the metal layers in the first board region extends to the second board region, and a part of the metal layers extending to the second board region are configured to form at least a part of the reinforcing structure.

In a possible embodiment of the present disclosure, the reinforcing structure has a wedge-like structure.

In a possible embodiment of the present disclosure, the first support layer includes polyimide; and/or the second support layer includes polypropylene.

In a possible embodiment of the present disclosure, the reinforcing structure includes a first fixing glue arranged at a side of the flexible circuit board facing away from the bending direction of the second board region and/or arranged at a side of the flexible circuit board facing the bending direction of the second board region.

In another aspect, the present disclosure provides in some embodiments a display apparatus, including: the above-mentioned flexible circuit board; and a display panel. A binding pin of the flexible circuit board is bound to a binding pin of the display panel.

In a possible embodiment of the present disclosure, the display apparatus further includes: a first support structure arranged between a non-display side of the display panel and the flexible circuit board; and a second support structure. The display panel includes a bending region, the binding pin of the display panel is arranged at the bending region, the bending region is bent to a side of the first support structure away from a display side, and the second support structure is arranged between the first support structure and the bending region.

In a possible embodiment of the present disclosure, the display apparatus further includes a third support structure, an adhesive is arranged at both ends of the third support structure, the third support structure is arranged between the first support structure and the second board region, and the third support structure is arranged at a connection region between the first board region and the second board region.

In a possible embodiment of the present disclosure, the third support structure includes polyethylene terephthalate (PET).

According to the embodiments of the present disclosure, the flexible circuit board includes the first board region, the second board region and the reinforcing structure. The first board region is coupled to the second board region, and rigidity of the part of the flexible circuit board corresponding to the first board region is greater than that of the part of the flexible circuit board corresponding to the second board region, and the thickness of the part of the flexible circuit board corresponding to the first board region is greater than the thickness of the part of the flexible circuit board corresponding to the second board region, so as to bend the part of the flexible circuit board corresponding to the second board region, thereby to facilitate the connection of an opposing part and improve a spatial layout design of the display apparatus. Through the reinforcing structure at the connection region between the first board region and the second board region, it is able to improve the structural strength of the connection region, thereby to improve the bending resistance and the tensile strength of the connection region, and improve a serving life of the second board. As a result, it is able to prevent the wiring of the flexible circuit board from being adversely affected, ensure the display stability of the display apparatus, and prolong a service life of the flexible circuit board.

### BRIEF DESCRIPTION OF THE DRAWINGS

FIG. 1 is a schematic view of a flexible circuit board according to one embodiment of the present disclosure;

FIG. 2 is a schematic view of a first board region and a second board region of the flexible circuit board in FIG. 1;

FIG. 3 is a partial sectional view of the flexible circuit board in FIG. 1;

FIG. 4 is another schematic view of the flexible circuit board according to one embodiment of the present disclosure;

FIG. 5 is a partial sectional view of the flexible circuit board in FIG. 3;

FIG. 6 is a schematic view of a dispensing position of a fixing glue according to one embodiment of the present disclosure;

FIG. 7 is another schematic view of the dispensing position of the fixing glue according to one embodiment of the present disclosure;

FIG. 8 is yet another schematic view of the dispensing position of the fixing glue according to one embodiment of the present disclosure;

FIG. 9 is still yet another schematic view of the dispensing position of the fixing glue according to one embodiment of the present disclosure;

FIG. 10 is still yet another schematic view of the dispensing position of the fixing glue according to one embodiment of the present disclosure;

FIG. 11 is still yet another schematic view of the dispensing position of the fixing glue according to one embodiment of the present disclosure;

FIG. 12 is a schematic view of a display apparatus where the second board region is not in a bending state according to one embodiment of the present disclosure;

FIG. 13 is a schematic view of the display apparatus where the second board region is in the bending state according to one embodiment of the present disclosure;

FIG. 14 is a schematic view of the display apparatus according to one embodiment of the present disclosure;

FIG. 15 is another schematic view of the display apparatus according to one embodiment of the present disclosure; and

FIG. 16 is a sectional view of a third support structure according to one embodiment of the present disclosure.

### DETAILED DESCRIPTION

The present disclosure will be described hereinafter in conjunction with the drawings and embodiments. The following embodiments are for illustrative purposes only, but shall not be used to limit the scope of the present disclosure. In the case of no conflict, the embodiments of the present disclosure and the features therein may be combined.

Such words as “first” and “second” are merely used to separate one entity or operation from another entity or operation, but are not necessarily used to represent or imply any relation or order between the entities or operations. In addition, such terms as “include” or “including” or any other variations involved in the present disclosure intend to provide non-exclusive coverage, so that a procedure, method, article or device including a series of elements may also include any other elements not listed herein, or may include any inherent elements of the procedure, method, article or device. If without any further limitations, for the elements defined by such sentence as “including one . . . ” , it is not excluded that the procedure, method, article or device including the elements may also include any other identical elements. The expression “more than two” refers to two or more.

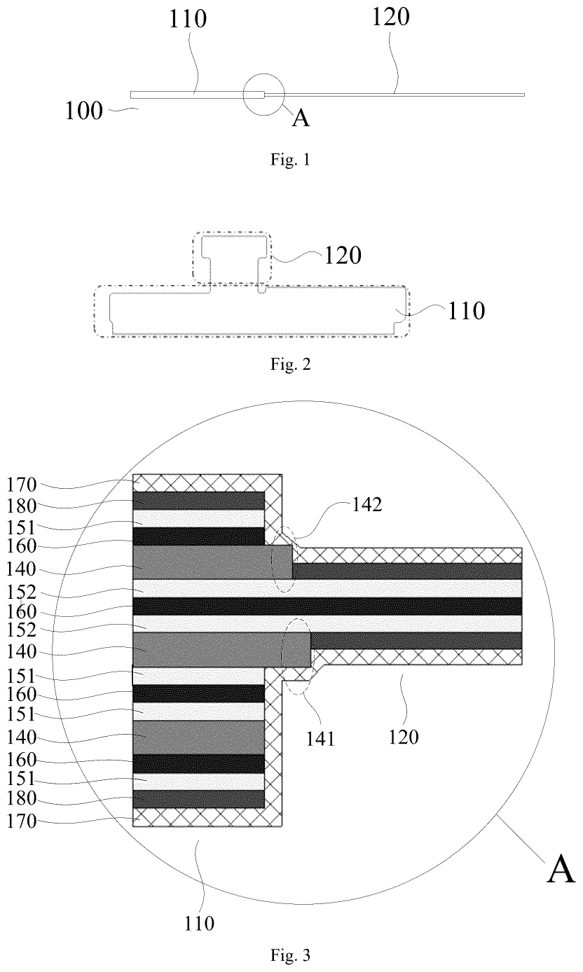

As shown in FIGS. 1 to 10, the present disclosure provides in some embodiments a flexible circuit board 100, which includes: a first board region 110, a second board region 120, and a connection region, the connection region being arranged between the first board region and the second board region, a thickness of a part of the flexible circuit board 100 corresponding to the first board region 110 being greater than a thickness of a part of the flexible circuit board 100 corresponding to the second board region 120, the part of the flexible circuit board 100 corresponding to the second board region 120 being used for bending, at least one first support layer 160 and at least one metal layer 150 being arranged on each of the first board region 110 and the second board region 120, and the first support layer 160 and the metal layer 150 being laminated one on another in a thickness direction of the flexible circuit board 100; and a reinforcing structure 130 arranged at the connection region.

It should be appreciated that, the flexible circuit board 100 in the embodiments of the present disclosure includes the first board region 110, the second board region 120, the connection region and the reinforcing structure 130. The first board region 110 is coupled to the second board region 120, and the connection region is arranged between the first board region and the second board region. Rigidity of the part of the flexible circuit board 100 corresponding to the first board region 110 is greater than rigidity of the part of the flexible circuit board 100 corresponding to the second board region 120, and the thickness of the part of the flexible circuit board 100 corresponding to the first board region 110 is greater than the thickness of the part of the flexible circuit board 100 corresponding to the second board region 120, so that the flexible circuit board 100 corresponding to the second board region 120 is bendable. Specifically, the second board region 120 includes a bending region and a connection region. The part of the flexible circuit board 100 corresponding to the first board region 110 is coupled to a first opposing part, and the second board region 120 is bent at the bending region such that a part of the flexible circuit board 100 corresponding to the connection region faces away from the first opposing part and is coupled to a second opposing part through the connection region, so as to facilitate a spatial layout design of a display apparatus 200. In the case that the flexible circuit board 100 is bent at the second board region 120, the bending starts at the connection region between the first board region 110 and the second board region 120, and stress concentration easily occur at the connection region. When the second board region 120 is in a bending state for a long time period, a fracture may occur at the connection region between the first board region 110 and the second board region 120, so the wiring of the flexible circuit board 100 may be adversely affected, and thereby a display defect may occur. Through the reinforcing structure 130 at the connection region between the first board region 110 and the second board region 120, it is able to increase the structural strength, the bending resistance and the tensile strength of the connection region, thereby to prolong a service life of the second board region 120. As a result, it is able to prevent the wiring of the flexible circuit board 100 from being adversely affected, ensure the display stability of the display apparatus 200, and prolong a service life of the flexible circuit board 100.

It should be appreciated that, the flexible circuit board 100 further includes the metal layer 150 and the first support layer 160. Specifically, the first support layer 160 and the metal layer 150 are laminated one on another in the thickness direction of the flexible circuit board 100. The metal layer 150 is used for electric conduction, and the first support layer 160 is configured to support the metal layer 150. The quantity of metal layers 150 and the quantity of first support layers 160 are plural, and at least one metal layer 150 and at least one first support layer 160 are arranged at each of the first board region 110 and the second board region 120. Specifically, the quantity of metal layers 150 at the first board region 110 is greater than the quantity of metal layers 150 at the second board region 120, and the quantity of first support layers 160 at the first board region 110 is greater than the quantity of first support layers 160 at the second board region 120, so that the thickness of the part of the flexible circuit board 100 corresponding to the first board region 110 is greater than the thickness of the part of the flexible circuit board 100 corresponding to the second board region 120. In this way, it is able to bend the part of the flexible circuit board 100 corresponding to the second board region 120 to a predetermined position while ensuring the overall performance of the flexible circuit board 100.

Illustratively, the first board region 110 includes four metal layers 150 and four first support layers 160, and the second board region 120 includes two metal layers 150 and one first metal layer 150. A thickness of the metal layer 150 is 10 microns to 20 microns, and a thickness of the first support layer 160 is 15 microns.

In some embodiments of the present disclosure, as shown in FIG. 3, the flexible circuit board 100 further includes a second support layer 140 arranged at the first board region 110, there is at least one second support layer 140 extending to the second board region 120, and the second support layer 140 on the second board region 120 forms at least a part of the reinforcing structure 130.

It should be appreciated that, the flexible circuit board 100 further includes the second support layer 140. Specifically, the second support layer 140 is arranged at the first board region 110 for support, so as to improve the structural strength. There is at least one second support layer 140 extending from the first board region 110 to the second board region 120. The second support layer 140 at the second board region 120 acts as the reinforcing structure 130. In the case that the second board region 120 is bent, the second support layer 140 supports the connection region between the first board region 110 and the second board region 120. In this way, it is able to improve the stress concentration at a bending start point, improve the bending resistance and the tensile strength, thereby to prolong the service life of the second board region 120

Illustratively, in a horizontal direction, an end surface of the second support layer 140 on the second board region 120 is provided with at least one convex and at least one concave, i.e., the end surface is of a wave-like or folded shape, so as to prevent the stress concentration at a same position of the second support layer 140 when the second board region 120 is bent. In this way, it is able to improve the stress concentration, thereby to further improve the structural strength of the connection region between the first board region 110 and the second board region 120.

In some embodiments of the present disclosure, as shown in FIG. 3, a dimension of the second support layer 140 at the second board region 120 is less than or equal to 1 mm in a direction from the first board region 110 to the second board region 120.

It should be appreciated that, in the direction from the first board region 110 to the second board region 120, when the second support layer 140 at the second board region 120 is too long, the overall structural strength of the second board region 120 is too large to be bent, and at this time, the assembling may be adversely affected. When the second support layer 140 at the second board region 120 is too short, the structural strength of the connection region between the first board region 110 and the second board region 120 is relatively weak, and the stress concentration may easily occur at the connection region. At this time, the connection region between the first board region 110 and the second board region 120 may be easily broken, so the wiring of the flexible circuit board 100 may be adversely affected and the display defect may occur. Hence, the dimension of the second support layer 140 at the second board region 120 is set to be less than or equal to 1 mm.

In some embodiments of the present disclosure, as shown in FIG. 3, there are at least two second support layers 140 extending to the second board region 120. In the second board region 120, the second support layer 140 facing away from a bending direction of the second board region 120 is a first extension layer 141, the second support layer 140 facing the bending direction of the second board region 120 is a second extension layer 142, and a dimension of the first extension layer 141 is larger than a dimension of the second extension layer 142 in the direction from the first board region 110 to the second board region 120.

It should be appreciated that, the quantity of second support layers 140 is plural, and at least two second support layers 140 extend to the second board region 120, so as to further improve the structural strength of the connection region between the first board region 110 and the second board region 120. In addition, a dimension of a part of the first extension layer 141 extending to the second board region 120 is greater than a dimension of a part of the second extension layer 142 extending to the second board region 120 in the direction from the first board region 110 to the second board region 120. In this way, it is able for the first extension layer 141 and the second extension layer 142 to meet the requirement on the bending of the second board region 120. When the second board region 120 is bent, a bending length of the flexible circuit board 100 away from the bending direction of the second board region 120 is greater than the bending length of the flexible circuit board 100 toward the bending direction of the second board region 120. Hence, when the first extension layer 141 is longer, it is able to improve the structural strength of the flexible circuit board 100 away from the bending direction of the second board region 120, and when the second extension layer 142 is longer, it is able to improve the structural strength of the flexible circuit board 100 toward the bending direction of the second board region 120.

It should be appreciated that, a difference in the dimensions of the first extension layer 141 and the second extension layer 142 is inversely proportional to a radius of curvature of the second board region 120. Specifically, the larger the radius of curvature of the second board region 120, the smaller the amount of deformation of the connection region between the first board region 110 and the second board region 120, and the smaller the stress concentration. At this time, it is able to reduce the difference between the bending length of the flexible circuit board 100 away from the bending direction of the second board region 120 and the bending length of the flexible circuit board 100 toward the bending direction of the second board region 120, and reduce the difference in the dimensions of the first extension layer 141 and the second extension layer 142, thereby to meet the requirement on the bending of the second board region 120 In some embodiments of the present disclosure, as shown in FIG. 3, the quantity of metal layers 150 at the first board region 110 is greater than the quantity of metal layers 150 at the second board region 120, and the metal layers 150 at the second board region 120 are arranged at a same layer as a part of the metal layers 150 at the first board region 110. The quantity of first support layers 160 at the first board region 110 is greater than the quantity of first support layers 160 at the second board region 120, and the first support layers 160 at the second board region 120 are arranged at a same layer as a part of the first support layers 160 at the first board region 110. A shielding layer 170 is arranged at both sides of the flexible circuit board 100 in the thickness direction.

It should be appreciated that, the flexible circuit board 100 includes the metal layer 150, the first support layer 160 and the shielding layer 170. Specifically, the metal layer 150 is used for electric conduction, the quantity of metal layers 150 is plural, and the quantity of metal layers 150 in the first board region 110 is greater than the quantity of metal layers 150 in the second board region 120. A part of the metal layers 150 are merely arranged in the first board region 110, and the other metal layers 150 are arranged in both the first board region 110 and the second board region 120. The second support layer 140 and the first support layer 160 are laminated one on another on the metal layer 150 to support the metal layer 150 and improve the overall structural strength of the flexible circuit board 100. The quantity of first support layers 160 is plural, and the quantity of first support layers 160 in the first board region 110 is greater than the quantity of first support layers 160 in the second board region 120. A part of the first support layers 160 are merely arranged in the first board region 110, and the other first support layers 160 are arranged in both the first board region 110 and the second board region 120. The shielding layer 170 is configured to shield electromagnetic signals from the outside, so as to prevent the occurrence of signal interference, and improve the operating stability of the flexible circuit board 100. The quantity of each of the metal layers 150, the second support layers 140 and the first support layers 160 in the first board region 110 is greater than that in the second board region 120, so the thickness of the part of the flexible circuit board 100 corresponding to the first board region 110 is greater than the thickness of the part of the flexible circuit board 100 corresponding to the second board region 120.

Illustratively, the flexible circuit board 100 further includes a cover film 180 that covers the metal layer 150 adjacent to the shielding layer 170, so as to protect the metal layer 150.

Illustratively, the metal layers 150 of the flexible circuit board 100 include a first metal layer 151 and a second metal layer 152. The first metal layer 151 is merely arranged at the first board region 110 and the second metal layer 152 is arranged at both the first board region 110 and the second board region 120. There are four first metal layers 151 and two second metal layers 152. One first support layer 160 is arranged between the two second metal layers 152. There are two second support layers 140 arranged at a side of the second metal layer 152 away from the first support layer 160 and extending from the first board region 110 to the second board region 120. The second support layer 140 facing away from the bending direction of the second board region 120 serves as the first extension layer 141, and the second support layer 140 facing the bending direction of the second board region 120 serves as the second extension layer 142. In the direction from the first board region 110 to the second board region 120, the difference between the dimensions of the first extension layer 141 and the second extension layer 142 is larger than a sum of thicknesses of the two second metal layers 152 and the first support layer 160 between the two second metal layers 152. In this way, the second support layer 140 extending to the second board region 120 serves as the reinforcing structure 130, so as to improve the stress concentration at the connection region between the first board region 110 and the second board region 120.

Illustratively, the first support layer 160 is a polyimide support layer having a thickness of 15 microns, and there are four first support layers 160 in the first board region 110, with one of the first support layers 160 extending to the second board region 120. The second support layer 140 is a polypropylene support layer having a thickness of 40 microns, and there are three second support layers 140 in the first board region 110, with two of the second support layers 140 extending to the second board region 120. A dimension of the second support layer 140 extending into the second board region 120 towards the bending direction is shorter by 1 mm than a dimension of the second support layer 140 extending into the second board region 120 away from the bending direction. An outermost layer of the laminated structure in each of the first board region and the second board region is the shielding layer, and a thickness of the shielding layer 170 in the first board region 110 is equal to that in the second board region 120, i.e., both 15 microns. The cover film 180 is arranged at both the first board region and the second board region to cover the metal layer 150 close to the shielding layer 170, and a thickness of the cover film 180 at the first board region 110 is equal to that at the second board region 120, i.e., both 15 microns.

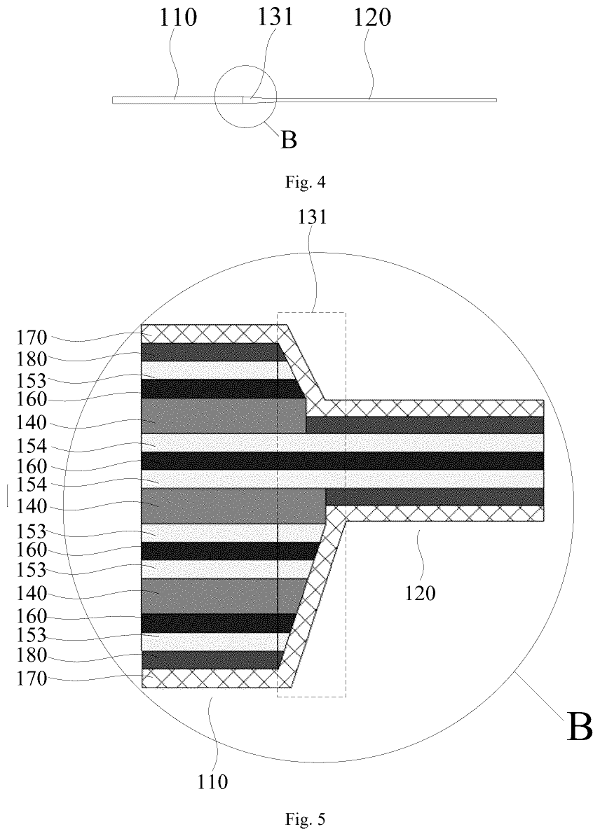

In some embodiments of the present disclosure, as shown in FIGS. 4 and 5, at least one of the first support layers 160 in the first board region 110 extends to the second board region 120, and a part of the first support layers 160 extending to the second board region 120 form at least a part of the reinforcing structure 130; and/or at least one of the metal layers 150 in the first board region 110 extends to the second board region 120, and a part of the metal layers 150 extending to the second board region 120 form at least a part of the reinforcing structure 130.

It should be appreciated that, there is at least one first support layer 160 in the first board region 110 extending to the second board region 120, and the first support layer 160 extending to the second board region 120 forms at least a part of the reinforcing structure 130, so as to increase the structural strength of the connection region between the first board region 110 and the second board region 120, thereby to improve the stress concentration. At least one metal layer 150 in the first board region 110 extends to the second board region 120, and the metal layer 150 extending to the second board region 120 forms at least a part of the reinforcing structure 130, so as to increase the structural strength of the connection region between the first board region 110 and the second board region 120, thereby to improve the stress concentration. The metal layer 150, the second support layer 140 and the first support layer 160 extending to the second board region 120 together form the reinforcing structure 130, so as to further improve the bending resistance and the tensile strength of the connection region, thereby to improve the service life of the second board region 120. In this way, it is able to prevent the wiring of the flexible circuit board 100 from being adversely affected, ensure the display stability of the display apparatus 200, and prolong the service life of the flexible circuit board 100.

In some embodiments of the present disclosure, as shown in FIGS. 4 and 5, the reinforcing structure 130 is a wedge-like structure 131.

It should be appreciated that, the reinforcing structure 130 is a wedge-like structure 131. Specifically, the metal layer 150, the second support layer 140 and the first support layer 160 extending to the second board region 120 as well as the shielding layer 170 are arranged obliquely toward the second board region 120 to form the wedge-like structure 131. In the thickness direction of the flexible circuit board 100, there is a wedge-like transition between the thicker first board region 110 and the thinner second board region 120, so it is able to increase the structural strength of the connection region between the first board region 110 and the second board region 120 through the metal layer 150, the second support layer 140 and the first support layer 160 in the reinforcing structure 130, thereby to improve the stress concentration. In this way, it is able to further improve the bending resistance and the tensile strength of the connection region, thereby to improve the service life of the second board region 120, prevent the wiring of the flexible circuit board 100 from being adversely affected, ensure the display stability of the display apparatus 200, and prolong the service life of the flexible circuit board 100. In addition, in a direction from the first board region 110 to the second board region 120, an inclination angle of the wedge-like structure 131 is 30 degrees to 60 degrees.

Illustratively, the metal layers 150 of the flexible circuit board 100 include a third metal layer 153 and a fourth metal layer 154, which each have a thickness of 15 microns. There are four third metal layer 153 arranged at the first board region 110 and extending to the connection region between the first board region 110 and the second board region 120, and the third metal layer 153 extending to the second board region 120 forms a part of the reinforcing structure 130. There are two fourth metal layer 154 arranged at both the first board region 110 and the second board region 120. There are four first support layers 160 each having a thickness of 15 microns. Three first support layers 160 are arranged at the first board region 110 and extend to the connection region between the first board region 110 and the second board region 120, and the first support layers 160 extending to the second board region 120 form a part of the reinforcing structure 130. The remaining first support layer 160 is arranged between the two fourth metal layers 154. There are three second support layers 140 each having a thickness of 40 microns. Each second support layer 140 is arranged at the first board region 110 and extends to the connection region between the first board region 110 and the second board region 120, and the second support layers 140 extending to the second board region 120 forms a part of the reinforcing structure 130. In the thickness direction of the flexible circuit board 100, the layer closer to the fourth metal layer 154 extends farther to the connection region between the first board region 110 and the second board region 120, so as to form the wedge-like structure 131. In addition, in the direction from the first board region 110 to the second board region 120, an inclination angle of the wedge-like structure 131 is 30 degrees.

In some embodiments of the present disclosure, the second support layer 140 includes polypropylene; and/or, the first support layer 160 includes polyimide.

It should be appreciated that, the second support layer 140 is made of polypropylene, which has excellent chemical resistance, heat resistance, electrical insulation, mechanical performance and abrasion resistance, so it is able to improve the structural strength of the flexible circuit board 100. The first support layer 160 is made of polyimide, as a film-type insulating material, which has excellent high and low temperature resistance, electrical insulation, adhesion, radiation resistance and medium resistance. Illustratively, the cover film 180 includes a thermosetting film made of epoxy resin.

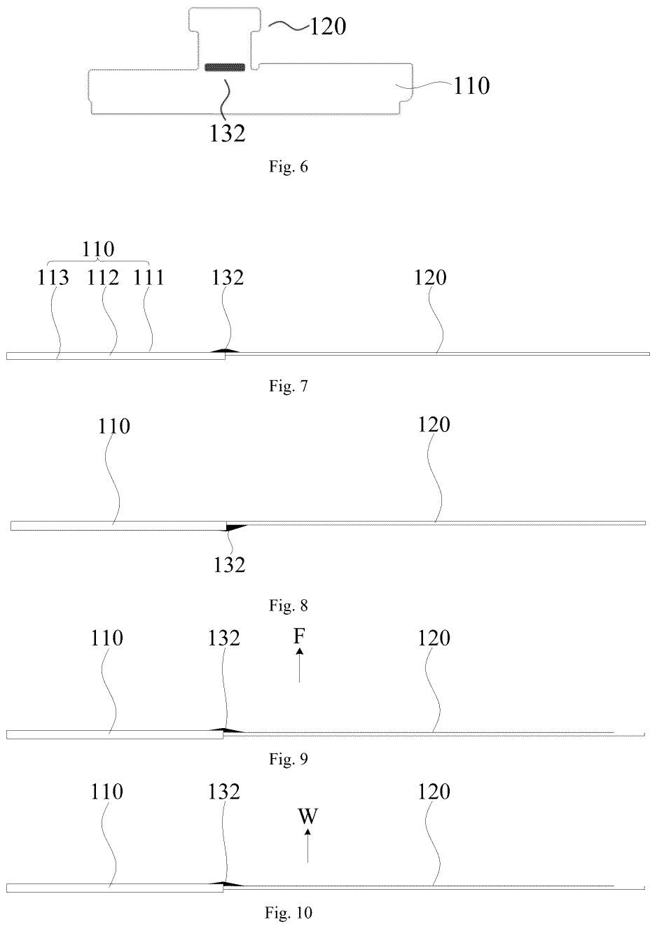

In some embodiments of the present disclosure, as shown in FIGS. 6 to 11, the reinforcing structure 130 includes a first fixing glue 132 arranged at a side of the flexible circuit board 100 away from the bending direction of the second board region 120, and/or at a side of the flexible circuit board 100 facing the bending direction of the second board region 120.

It should be appreciated that, the reinforcing structure 130 further includes the first fixing glue 132. The first fixing glue 132 is applied to the connection region between the first board region 110 and the second board region 120 through a dispensing process, so as to improve the structural strength of the connection region. A specific position of the first fixing glue is determined according to the practical need. Specifically, in the thickness direction of the flexible circuit board 100, the first board region 110 includes a bottom layer 113 coupled to a display panel 210, a top layer 111 arranged away from the bottom layer 113, and an intermediate layer 112 arranged between the bottom layer 113 and the top layer 111.

As shown in FIG. 7, the second board region 120 is coupled to the top layer 111 of the first board region 110. At this time, in the thickness direction of the flexible circuit board 100, the second board region 120 is flush with the top layer 111, i.e., there is no level difference therebetween. The first fixing glue 132 is arranged at a side of the flexible circuit board 100 facing the bending direction of the second board region 120, and the first fixing glue 132 is applied to the top layer 111 and a side of the second board region 120 close to the top layer 111.

As shown in FIG. 8, it should be appreciated that, a thickness of the first fixing glue 132 is less than 0.2 mm. In the case that the second board region 120 is attached to the top layer 111 of the first board region 110, e.g., in the case of assembling, there is a thickness limit at both the top layer 111 and the bottom layer 113 of the first board region 110. At this time, the first fixing glue 132 is applied to a side facing away from the bending direction of the second board region 120, so that the first fixing glue 132 is merely located between the bottom layer 113 and the second board region 120 at a position where the level difference occurs. The first fixing glue 132 is not applied to the bottom layer 113. In this way, it is able to prevent the overall thickness of the flexible circuit board 100 from being adversely affected while improving the structural strength of the connection region between the first board region 110 and the second board region 120.

As shown in FIG. 9, it should be appreciated that, a thickness of the first fixing glue 132 is less than 0.2 mm. In the case that the second board region 120 is attached to the top layer 111 of the first board region 110, e.g., in the case of assembling, there is a thickness limit of the top layer 111 of the first board region 110, and it is impossible to apply the first fixing flue to the top layer 111. At this time, the first fixing glue 132 is applied to a side away from the bending direction of the second board region 120, i.e., a back side F away from the bending direction. In other words, the first fixing glue 132 is applied to the bottom layer 113, a side of the second board region 120 close to the bottom layer 113, and a position between the bottom layer 113 and the second board region 120 where the level difference occurs.

As shown in FIG. 10, the second board region 120 is coupled to the intermediate layer 112 of the first board region 110. At this time, in the thickness direction of the flexible circuit board 100, there are a level difference between the second board region 120 and the top layer 111 and a level difference between the second board region 120 and the bottom layer 113. Depending on the actual situations, the first fixing glue 132 is applied to the top layer 111, a side of the second board region 120 close to the top layer 111 and a position between the top layer 111 and the second board region 120 where the level difference occurs, or applied to the bottom layer 113, a side of the second board region 120 close to the bottom layer 113 and a position between the bottom layer 113 and the second board region 120 where the level difference occurs. The first fixing glue 132 is applied to a side facing the bending direction W.

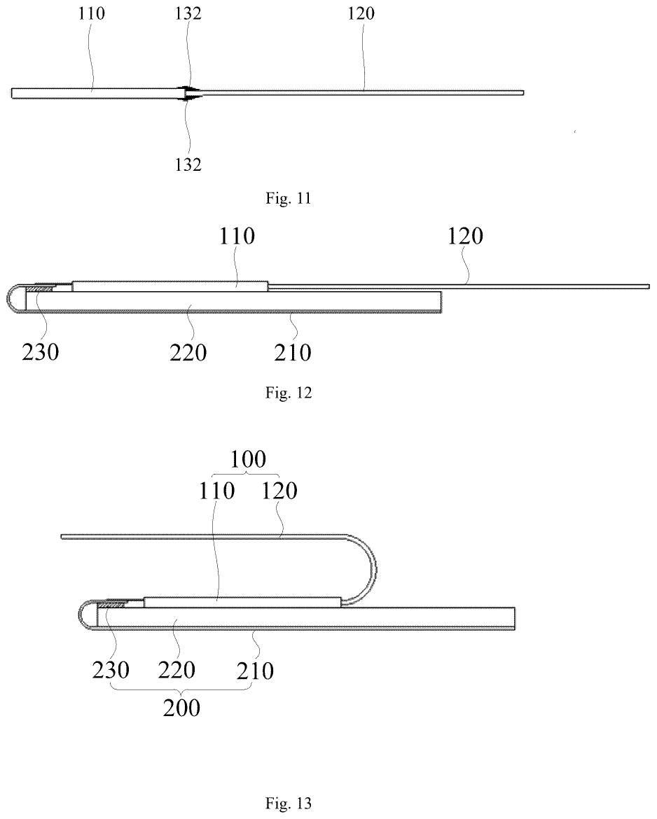

As shown in FIG. 11, the reinforcing structure 130 between the first board region 110 and the second board region 120 is a wedge-like structure 131, so that a first oblique surface is formed between the second board region 120 and the top layer 111, and a second oblique surface is formed between the second board region 120 and the bottom layer 113. The first fixing glue 132 is applied to the first oblique surface and/or the second oblique surface. Through the first fixing glue 132, it is able to improve the structural strength of the wedge-like structure 131, thereby to improve the bending resistance of the second board region 120.

Through comparing the flexible circuit board 100 with the first fixing glue 132 and the flexible circuit board 100 without the reinforcing structure 130, it is found that, when the flexible circuit board 100 with the first fixing glue 132 is bent by 90°, and the quantity of times of bending the second board region 120 is significantly increased by about 63%, and when it is bent by 180°, and the quantity of times of bending the second board region 120 is significantly increased by about 60%.

As shown in FIGS. 12 to 16, the present disclosure further provides in some embodiments a display apparatus 200, which includes: the above-mentioned flexible circuit board 100; and a display panel 210. A binding pin of the flexible circuit board 100 is bound to a binding pin of the display panel 210.

It should be appreciated that, the display apparatus 200 includes the above-mentioned flexible circuit board 100, so it has all the beneficial effects of the flexible circuit board 100, which will not be particularly defined herein. During the assembling of the display panel 210 with the flexible circuit board 100, the binding pin of the flexible circuit board 100 is bound to the binding pin of the display panel 210. As shown in FIG. 11, after the assembling of the display panel 210 with the flexible circuit board 100, the second board region 120 is in a non-bending state. As shown in FIG. 12, the second board region 120 is bent to a direction away from a display side of the display panel 210, so as to satisfy the requirement on the assembling of the second board region 120 with the opposing part.

In some embodiments of the present disclosure, as shown in FIGS. 12 to 16, the display apparatus 200 further includes: a first support structure 220 arranged between a non-display side of the display panel 210 and the flexible circuit board 100; and a second support structure 230. The display panel 210 includes a bending region, the binding pin of the display panel 210 is arranged at the bending region, and a part of the display panel 210 at the bending region is bent to a side of the first support structure 220 away from the display side. The second support structure 230 is arranged between the first support structure 220 and the part of the display panel 210 at the bending region.

It should be appreciated that, the display apparatus 200 further includes the first support structure 220 and the second support structure 230. The first support structure 220 is arranged between the non-display side of the display panel 210 and the flexible circuit board 100, so as to support the first board region 110. The flexible circuit board 100 is arranged at the non-display side of the display panel 210, so the display panel 210 is provided with the bending region and the binding pin of the display panel 210 is arranged at the bending region. After the display panel 210 at the bending region is bent in a direction away from the display side, the binding pin of the display panel 210 is located at the non-display side, so as to facilitate the connecting between the binding pin of the flexible circuit board 100 and the binding pin of the display panel 210. In addition, the second support structure 230 is arranged between the first support structure 220 and the display panel 210 at the bending region, so as to support the binding pin of the flexible circuit board 100 and the binding pin of the display panel 210, thereby to ensure the connection stability.

Illustratively, an adhesive is arranged between the first support structure 220 and the part of the flexible circuit board 100 corresponding to the first board region 110, so as to enable the first support structure 220 to be firmly coupled to the flexible circuit board 100 at the first board region 110.

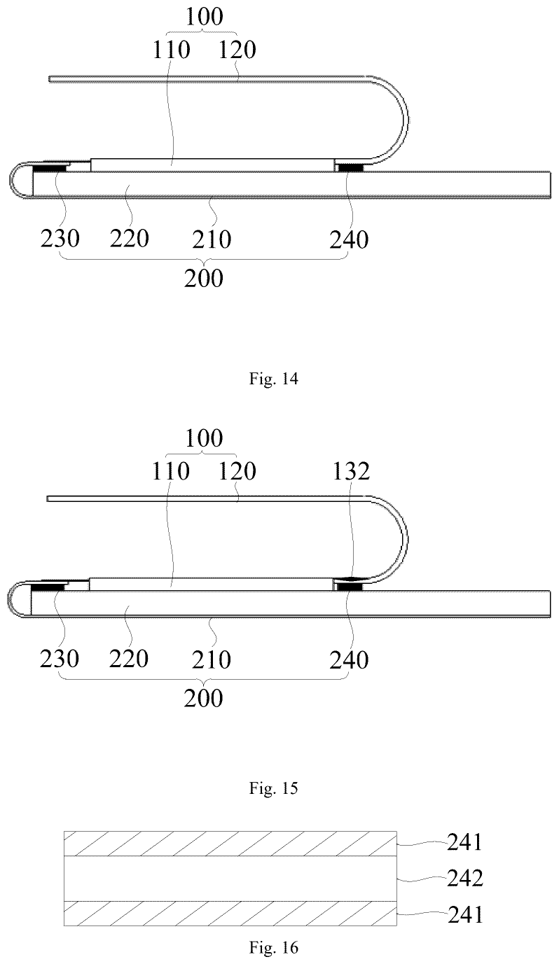

In some embodiments of the present disclosure, as shown in FIGS. 14 to 16, the display apparatus 200 further includes a third support structure 240, an adhesive 241 is arranged at both ends of the third support structure, the third support structure 240 is arranged between the first support structure 220 and the part of the flexible circuit board 100 corresponding to the second board region 120, and the third support structure 240 is arranged at the connection region between the first board region 110 and the second board region 120.

It should be appreciated that, the display apparatus 200 further includes the third support structure 240. Specifically, the adhesive 241 is arranged at both ends of the third support structure 240, so that one end of the third support structure 240 is adhered to the first support structure 220, and the other end of the third support structure 240 is adhered to the connection region between the first board region 110 and the second board region 120. In this way, it is able to pull the part of the flexible circuit board 100 corresponding to the connection region through the third support structure 240, thereby to secure the part of the flexible circuit board 100 corresponding to the connection region to the first support structure 220. On the one hand, it is able to bend the flexible circuit board merely in the second board region 120 and reduce the stress concentration at the connection region due to different rigidity, thereby to prevent the occurrence of fractures at the connection region. On the other hand, it is able to increase an area of the adhesive between the flexible circuit board 100 and the first support layer 160, thereby to further improve the connection stability therebetween.

Illustratively, as shown in FIG. 15, the second board region 120 is coupled to the top layer 111 of the first board region 110, and there is a level difference between the bottom layer 113 and the second board region 120. The third support structure 240 is arranged at a position where the level difference occurs, so as to pull the flexible circuit board 100 at the connection region, thereby to secure the flexible circuit board 100 at the connection region to the first support structure 220. At the same time, the first fixing glue 132 is applied to the top layer 111 and a side of the second board region 120 close to the top layer 111, so as to further improve the structural strength of the connection region between the first board region 110 and the second board region 120, improve the stress concentration at the bending start point, and improve the bending resistance and the tensile strength, thereby to improve the service life of the second board region 120.

In some embodiments of the present disclosure, the third support structure 240 includes PET.

It should be appreciated that, a base 242 of the third support structure 240 is made of PET which has excellent toughness and electrical insulation performance, so as to prevent the flexible circuit board 100 from being adversely affected, thereby to improve the stability.

The embodiments are for illustrative purposes only, but shall not be used to limit the scope of the present disclosure. In light of the present disclosure, a person skilled in the art may make various modifications and alterations without departing from the spirit of the present disclosure and the scope defined by the appended claims. Any modifications, equivalents or improvements made within the scope of the spirit and principle of the present disclosure shall be subject to the scope of the appended claims.

Although the preferred embodiments are described above, a person skilled in the art may make modifications and alterations to these embodiments in accordance with the basic concept of the present disclosure. So, the attached claims are intended to include the preferred embodiments and all of the modifications and alterations that fall within the scope of the present disclosure.

Obviously, a person skilled in the art may make further modifications and improvements without departing from the spirit of the present disclosure, and these modifications and improvements shall also fall within the scope of the present disclosure.

1. A flexible circuit board, comprising:
a first board region, a second board region and a connection region arranged between the first board region and the second board region, a thickness of a part of the flexible circuit board corresponding to the first board region being greater than a thickness of a part of the flexible circuit board corresponding to the second board region, the part of the flexible circuit board corresponding to the second board region being used for bending, at least one first support layer and at least one metal layer being arranged at each of the first board region and the second board region, and the first support layer and the metal layer being laminated one on another in a thickness direction of the flexible circuit board; and
a reinforcing structure arranged at the connection region.

2. The flexible circuit board according to claim 1, further comprising second support layers arranged at the first board region, wherein there is at least one second support layer extending to the second board region, and the second support layer at the second board region is configured to form at least a part of the reinforcing structure.

3. The flexible circuit board according to claim 2, wherein a dimension of the second support layer in the second board region is less than or equal to 1 mm in a direction from the first board region to the second board region.

4. The flexible circuit board according to claim 3, wherein there are at least two second support layers extending to the second board region; and
in the second board region, the second support layer facing away from a bending direction of the second board region is a first extension layer, the second support layer facing the bending direction of the second board region is a second extension layer, and a dimension of the first extension layer is greater than a dimension of the second extension layer in the direction from the first board region to the second board region.

5. The flexible circuit board according to claim 2, wherein the quantity of metal layers in the first board region is greater than the quantity of metal layers in the second board region, and the metal layers in the second board region are arranged at a same layer as a part of the metal layers in the first board region;
the quantity of first support layers in the first board region is greater than the quantity of first support layers in the second board region, and the first support layers in the second board region are arranged at a same layer as a part of the first support layers in the first board region; and
a shielding layer is arranged at both sides of the flexible circuit board in the thickness direction.

6. The flexible circuit board according to claim 5, wherein at least one of the first support layers in the first board region extends to the second board region, and a part of the first support layers extending to the second board region are configured to form at least a part of the reinforcing structure; and/or
at least one of the metal layers in the first board region extends to the second board region, and a part of the metal layers extending to the second board region are configured to form at least a part of the reinforcing structure.

7. The flexible circuit board according to claim 6, wherein the reinforcing structure has a wedge-like structure.

8. The flexible circuit board according to claim 6, wherein the first support layer comprises polyimide; and/or
the second support layer comprises polypropylene.

9. The flexible circuit board according to claim 1, wherein the reinforcing structure comprises a first fixing glue arranged at a side of the flexible circuit board facing away from the bending direction of the second board region and/or arranged at a side of the flexible circuit board facing the bending direction of the second board region.

10. A display apparatus, comprising:
the flexible circuit board according to claim 1; and
a display panel, wherein a binding pin of the flexible circuit board is bound to a binding pin of the display panel.

11. The display apparatus according to claim 10, further comprising:
a first support structure arranged between a non-display side of the display panel and the flexible circuit board; and
a second support structure,
wherein the display panel comprises a bending region, the binding pin of the display panel is arranged at the bending region, the bending region is bent to a side of the first support structure away from a display side, and the second support structure is arranged between the first support structure and the bending region.

12. The display apparatus according to claim 11, further comprising a third support structure, wherein an adhesive is arranged at both ends of the third support structure, the third support structure is arranged between the first support structure and the second board region, and the third support structure is arranged at a connection region between the first board region and the second board region.

13. The display apparatus according to claim 12, wherein the third support structure comprises polyethylene terephthalate (PET).

14. The display apparatus according to claim 10, wherein the flexible circuit board further comprises second support layers arranged at the first board region, wherein there is at least one second support layer extending to the second board region, and the second support layer at the second board region is configured to form at least a part of the reinforcing structure.

15. The display apparatus according to claim 14, wherein a dimension of the second support layer in the second board region is less than or equal to 1 mm in a direction from the first board region to the second board region.

16. The display apparatus according to claim 15, wherein there are at least two second support layers extending to the second board region; and
in the second board region, the second support layer facing away from a bending direction of the second board region is a first extension layer, the second support layer facing the bending direction of the second board region is a second extension layer, and a dimension of the first extension layer is greater than a dimension of the second extension layer in the direction from the first board region to the second board region.

17. The display apparatus according to claim 14, wherein the quantity of metal layers in the first board region is greater than the quantity of metal layers in the second board region, and the metal layers in the second board region are arranged at a same layer as a part of the metal layers in the first board region;
the quantity of first support layers in the first board region is greater than the quantity of first support layers in the second board region, and the first support layers in the second board region are arranged at a same layer as a part of the first support layers in the first board region; and
a shielding layer is arranged at both sides of the flexible circuit board in the thickness direction.

18. The display apparatus according to claim 17, wherein at least one of the first support layers in the first board region extends to the second board region, and a part of the first support layers extending to the second board region are configured to form at least a part of the reinforcing structure; and/or
at least one of the metal layers in the first board region extends to the second board region, and a part of the metal layers extending to the second board region are configured to form at least a part of the reinforcing structure.

19. The display apparatus according to claim 18, wherein the reinforcing structure has a wedge-like structure.

20. The display apparatus according to claim 18, wherein the first support layer comprises polyimide; and/or
the second support layer comprises polypropylene.
